(19) United States
(12) Patent Application Publication
(10) Pub. No.: US 2015/0229311 A1
(43) Pub. Date: Aug. 13, 2015

(54) OSCILLATOR FREQUENCY DIVIDER WITH IMPROVED PHASE NOISE

(71) Applicant: Nvidia Corporation, Santa Clara, CA (US)

(72) Inventors: Frank Zhang, Richardson, TX (US); Mehmet T. Ozgun, Plano, TX (US)

(73) Assignee: Nvidia Corporation, Santa Clara, CA (US)

(21) Appl. No.: 14/176,290

(22) Filed: Feb. 10, 2014

(51) Int. Cl. H03K 21/02

(52) U.S. Cl. CPC H03K 21/02

(57) ABSTRACT

A gated divider circuit includes a windowing unit configured to generate windowing waveforms from input oscillator waveforms having a fixed duty cycle. Additionally, the gated divider circuit includes a gated output unit coupled to the windowing unit and configured to provide selected ones of the input oscillator waveforms as controlled by corresponding selected ones of the windowing waveforms. Also included are a method of operating a gated divider circuit and a frequency conversion system employing a gated divider circuit as a local oscillator divider.

### TECHNICAL FIELD

This application is directed, in general, to waveform stabilization and, more specifically, to a gated divider circuit, a method of operating a gated divider circuit and a frequency conversion system employing the same.

### BACKGROUND

Frequencies generated by a frequency synthesizer employed in a transceiver are usually integer multiples of a final local oscillator (LO) frequency needed for frequency up-conversion or down-conversion. This requirement generally dictates that frequency dividers are required, and a LO frequency divider providing a 25 percent duty cycle (25% DC) is needed for optimal transceiver performance. Such frequency dividers may directly employ combinational logic circuits that typically introduce additional timing jitter. This timing jitter and its corresponding broadening of an associated frequency spectrum provide phase noise that is disruptive to these frequency synthesizers. To lower this phase noise, larger semiconductor die area and higher power consumption is required. Therefore, improvements in this area would prove beneficial to the art.

### SUMMARY

Embodiments of the present disclosure provide a gated divider circuit, a method of operating a gated divider circuit and a frequency conversion system.

In one embodiment, the gated divider circuit includes a windowing unit configured to generate windowing waveforms from input oscillator waveforms having a fixed duty cycle. Additionally, the gated divider circuit also includes a gated output unit coupled to the windowing unit and configured to provide selected ones of the input oscillator waveforms as controlled by corresponding selected ones of the windowing waveforms.

In another aspect, the method of operating a gated divider circuit includes providing oscillator waveforms having a fixed duty cycle and generating windowing waveforms based on the oscillator waveforms. The method also includes selecting ones of the oscillator waveforms as controlled by corresponding ones of the windowing waveforms.

In a further aspect, the frequency conversion system includes a local oscillator divider, having a windowing unit that generates windowing waveforms from local oscillator waveforms with a fixed duty cycle and a gated output unit that provides selected ones of the local oscillator waveforms as controlled by corresponding selected ones of the windowing waveforms. The frequency conversion system also includes a mixer that provides a converted waveform from the selected ones of the local oscillator waveforms and a reference waveform.

The foregoing has outlined preferred and alternative features of the present disclosure so that those skilled in the art may better understand the detailed description of the disclosure that follows. Additional features of the disclosure will be described hereinafter that form the subject of the claims of the disclosure. Those skilled in the art will appreciate that they can readily use the disclosed conception and specific embodiment as a basis for designing or modifying other structures for carrying out the same purposes of the present disclosure.

### BRIEF DESCRIPTION

Reference is now made to the following descriptions taken in conjunction with the accompanying drawings, in which:

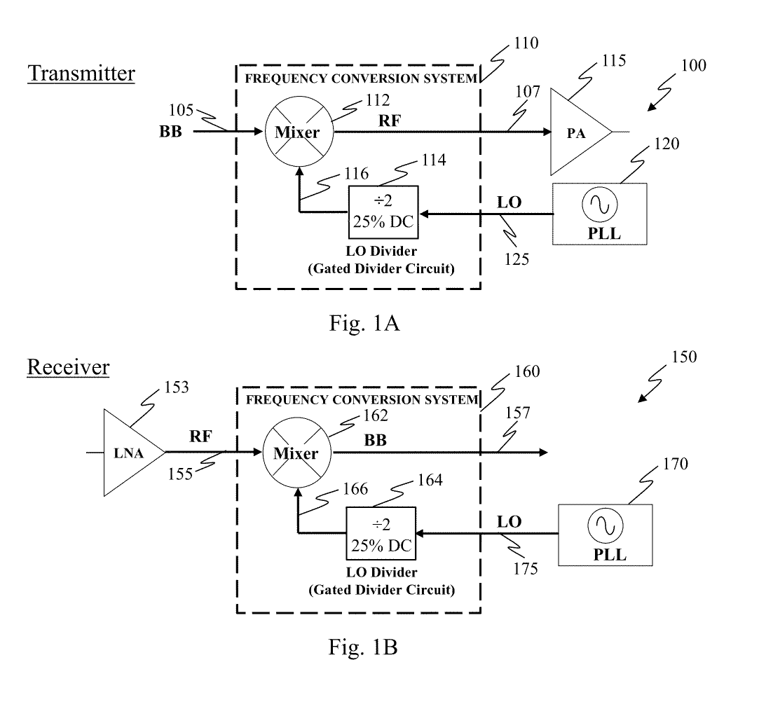

FIGS. 1A and 1B illustrate examples of transmitter and receiver portions of a transceiver constructed according to the principles of the present disclosure;

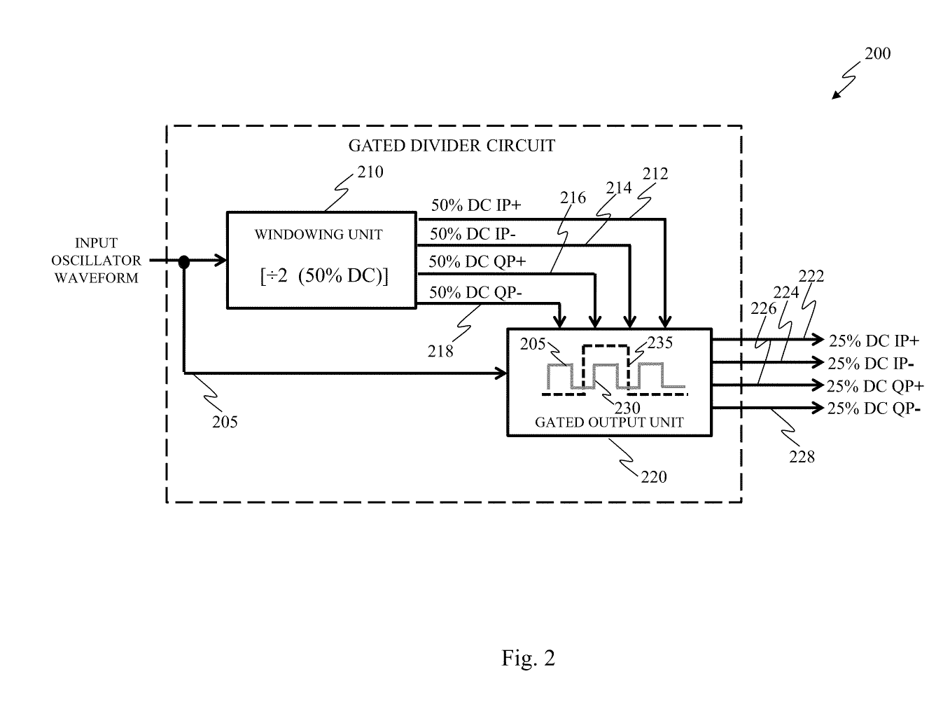

FIG. 2 illustrates a block diagram of an embodiment of a gated divider circuit constructed according to the principles of the present disclosure;

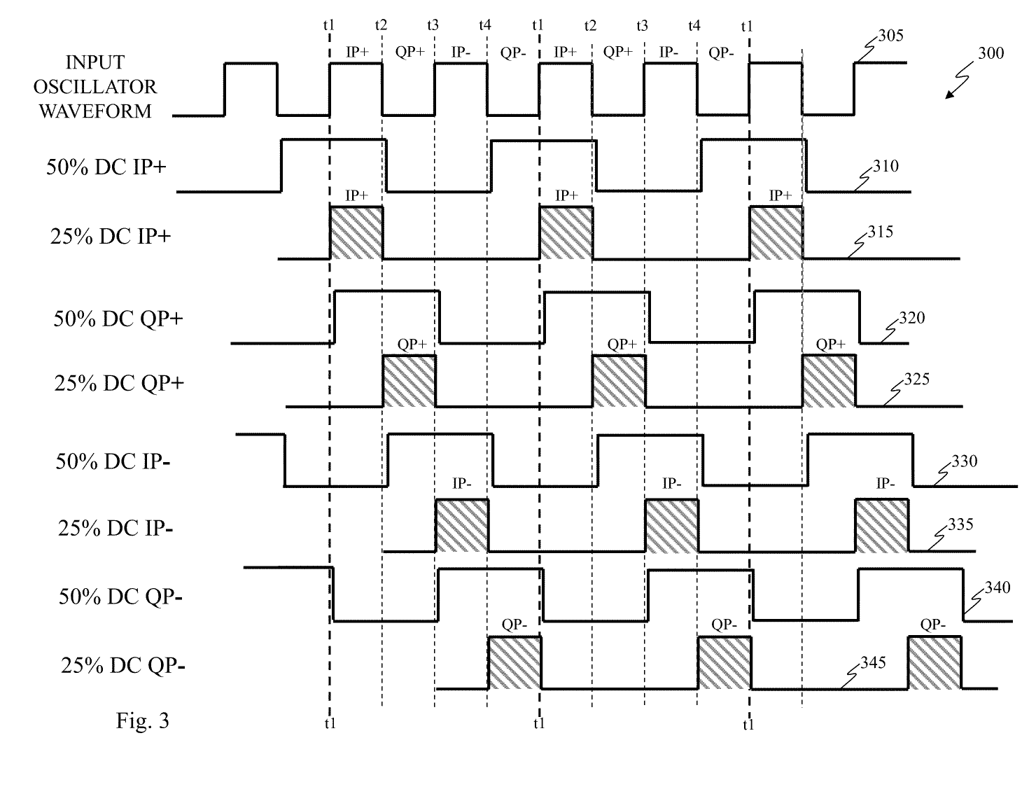

FIG. 3 illustrates a timing diagram of waveforms corresponding to the gated divider circuit of FIG. 2;

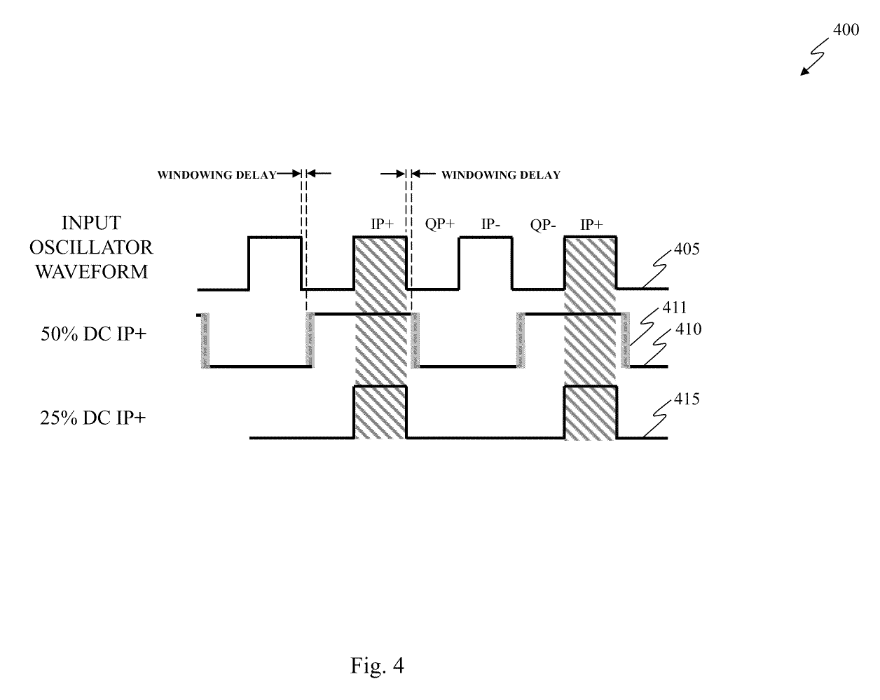

FIG. 4 illustrates another timing diagram showing more clearly a windowing delay or offset of a windowing waveform that frames selected ones of an input oscillator waveform such as the input oscillator waveform of FIG. 3;

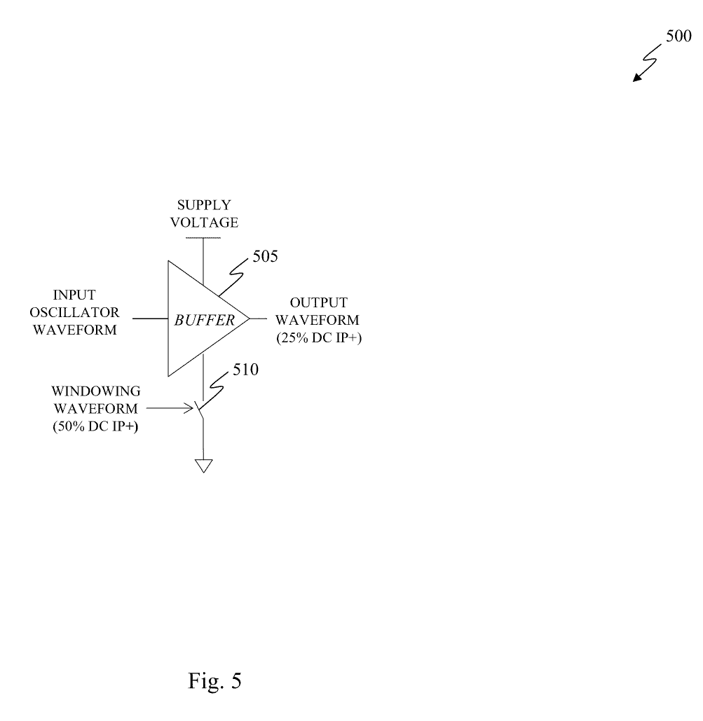

FIG. 5 illustrates an implementation example of a gated divider circuit constructed according to the principles of the present disclosure; and

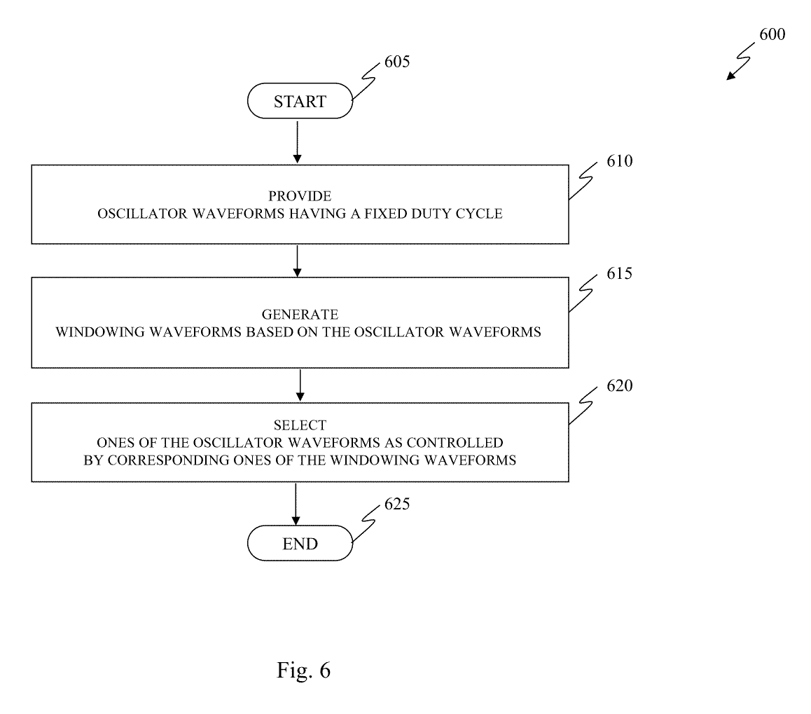

FIG. 6 illustrates a flow diagram of a method of operating a gated divider circuit carried out according to the principles of the present disclosure.

### DETAILED DESCRIPTION

FIGS. 1A and 1B illustrate examples of transmitter and receiver portions of a transceiver, generally designated 100 and 150, constructed according to the principles of the present disclosure. The transmitter portion 100 provides frequency conversion from a baseband (BB) frequency to a radio frequency (RF). The receiver portion 150 provides frequency conversion from the radio frequency to the baseband frequency, as shown.

The transmitter portion 100 includes a BB frequency input 105 to a frequency conversion system 110 having an RF output 107 to a power amplifier (PA) 115. The transmitter portion 100 also includes a phase locked loop (PPL) 120 having a local oscillator (LO) frequency input 125 to the frequency conversion system 110, as shown.

The frequency conversion system 110 includes a frequency mixer 112 and a local oscillator (LO) divider 114 (i.e., a gated divider circuit). The frequency mixer 112 employs the BB frequency input 105 and a divided output 116 from the LO divider 114 to provide the RF input 107 to the power amplifier (PA) 115. In this embodiment, the LO divider 114 divides the LO frequency output 125 by a factor of two and provides a 25 percent duty cycle waveform to the frequency mixer 112.

The receiver portion 150 includes a low noise amplifier (LNA) 153 that provides an RF input 155 to a frequency conversion system 160 having a BB frequency output 157. The receiver portion 150 also includes a phase locked loop (PPL) 170 having a local oscillator (LO) frequency input 175 to the frequency conversion system 160, as shown.

The frequency conversion system 160 includes a frequency mixer 162 and a local oscillator (LO) divider 164 (i.e., a gated divider circuit). The frequency mixer 162 employs the RF frequency input 155 and a divided output 166 from the LO divider 164 to provide the BB frequency output 157. In this embodiment, the LO divider 164 divides the LO frequency output 175 by a factor of two and provides a 25 percent duty cycle waveform to the frequency mixer 162.

FIG. 2 illustrates a block diagram of an embodiment of a gated divider circuit, generally designated 200, constructed according to the principles of the present disclosure. The gated divider circuit 200 includes a windowing unit 210 and a gated output unit 220. The windowing unit 210 receives an input oscillator waveform 205 and provides first, second, third and fourth windowing waveforms.

In this embodiment, these windowing waveforms are 50 percent duty cycle waveforms that correspond to in-phase windowing waveforms (50% DC IP+) 212, complementary in-phase windowing waveforms (50% DC IP−) 214, quadrature-phase windowing waveforms (50% DC QP+) 216 and complementary quadrature-phase windowing waveforms (50% DC QP−) 218 to the gated output unit 220.

The gated output unit 220 also receives the input oscillator waveform 205 and employs the first, second, third and fourth windowing waveforms (50% DC IP+) 212, (50% DC IP−) 214, (50% DC QP+) 216 and (50% DC QP−) 218 to control selection of the input oscillator waveforms 205. This selection respectively corresponds to first, second, third and fourth gated output waveforms that provide a 25 percent duty cycle and include in-phase output waveforms (25% DC IP+) 222, complementary in-phase output waveforms (25% DC IP−) 224, quadrature-phase output waveforms (25% DC QP+) 226 and complementary quadrature-phase output waveforms (25% DC QP−) 228, as shown.

The gated output unit 220 conceptually illustrates this windowing selection process. Here, a waveform portion 230 of the input oscillator waveform 205 is selected by a windowing waveform 235. This windowing selection process is more clearly illustrated below.

FIG. 3 illustrates a timing diagram, generally designated 300, of waveforms corresponding to the gated divider circuit 200 of FIG. 2. The timing diagram 300 includes an input oscillator waveform 305, a first windowing waveform (50% DC IP+) 310 that frames and provides gating for first selected ones (25% DC IP+) 315 of the input oscillator waveform 305.

In similar fashion, the timing diagram 300 also includes second, third and fourth windowing waveforms (50% DC QP+) 320, (50% DC IP−) 330 and (50% DC QP−) 340 that respectively frame and provide gating for second, third and fourth selected gated output waveforms (25% DC QP+) 325, (25% DC IP−) 335 and (25% DC QP−) 345 of the input oscillator waveform 305. Generally, all or a subset of the windowing waveforms and their corresponding selected gated output waveforms may be employed is a particular application.

FIG. 4 illustrates another timing diagram, generally designated 400, showing more clearly a windowing delay or offset of a windowing waveform that frames selected ones of an input oscillator waveform such as the input oscillator waveform 305 of FIG. 3. The timing diagram 400 includes an input oscillator waveform 405, a first windowing waveform (50% DC IP+) 410 that frames and provides gating for a first selected gated output waveform (25% DC IP+) 415 of the input oscillator waveform 405.

Conventionally, the first windowing waveform (50% DC IP+) 410 may be generated employing latch circuits or logic gating that inherently contain or cause timing delays with respect to the input oscillator waveform 405. Additionally, a windowing waveform timing jitter 411 may be introduced which correspondingly generates phase noise and broadens an associated corresponding frequency spectrum if employed to directly generate the in-phase or quadrature-phase selected gated output waveforms. However, when these intrinsic timing delays and jitter are employed to provide a windowing delay as shown, they guarantee the functionality of embodiments of the present disclosure.

FIG. 5 illustrates an implementation example of a gated divider circuit, generally designated 500, constructed according to the principles of the present disclosure. The gated divider circuit 500 employs the input and windowing waveforms 405, 410 discussed with respect to FIG. 4 to select and provide the gated output waveform 415 of FIG. 4. The gated divider circuit 500 includes a buffer 505 and a waveform selection switch 510.

Here, the buffer 505 receives the input oscillator waveform 405 and provides an output waveform that is at ground potential when the waveform selection switch 510 is not activated (open, as shown). When the windowing waveform 410 is positive, the waveform selection switch 510 is activated (closed) thereby allowing the output waveform to follow the input oscillator waveform 405.

The windowing waveform 410 is a 50 percent duty cycle waveform (50% DC IP+) that includes only one cycle of the input oscillator waveform 405 when positive, which corresponds to the first selected gated output waveform (25% DC IP+) having a 25 percent duty cycle. Of course, the gated divider circuit 500 may generally be applied to select any one of the selected gated output waveforms.

FIG. 6 illustrates a flow diagram of a method of operating a gated divider circuit, generally designated 600, carried out according to the principles of the present disclosure. The method 600 starts in a step 605 and oscillator waveforms having a fixed duty cycle are provided, in a step 610. Then, windowing waveforms based on the oscillator waveforms are generated in a step 615, and ones of the oscillator waveforms as controlled by corresponding ones of the windowing waveforms are selected, in a step 620.

In one embodiment, the fixed duty cycle of the input oscillator waveforms is a 50 percent duty cycle. In another embodiment, the windowing waveforms are 50 percent duty cycle waveforms. Accordingly, the corresponding selected ones of the windowing waveforms provide a windowing delay with respect to the selected ones of the input oscillator waveforms.

In a further embodiment, the selected ones of the input oscillator waveforms correspond to a 25 percent duty cycle waveform. In yet another embodiment, the selected ones of the input oscillator waveforms are selected from the group consisting of in-phase waveforms, complementary in-phase waveforms, quadrature-phase waveforms and complementary quadrature-phase waveforms. The method 600 ends in a step 625.

While the method disclosed herein has been described and shown with reference to particular steps performed in a particular order, it will be understood that these steps may be combined, subdivided, or reordered to form an equivalent method without departing from the teachings of the present disclosure. Accordingly, unless specifically indicated herein, the order or the grouping of the steps are not limitations of the present disclosure.

Those skilled in the art to which this application relates will appreciate that other and further additions, deletions, substitutions and modifications may be made to the described embodiments.

What is claimed is:

1. A gated divider circuit, comprising:
a windowing unit configured to generate windowing waveforms from input oscillator waveforms having a fixed duty cycle; and
a gated output unit coupled to the windowing unit and configured to provide selected ones of the input oscillator waveforms as controlled by corresponding selected ones of the windowing waveforms.

2. The circuit as recited in claim 1 wherein the corresponding selected ones of the windowing waveforms provide a windowing delay with respect to the selected ones of the input oscillator waveforms.

3. The circuit as recited in claim 1 wherein the input oscillator waveforms are local oscillator waveforms.

4. The circuit as recited in claim 1 wherein the windowing waveforms are 50 percent duty cycle waveforms.

5. The circuit as recited in claim 1 wherein the fixed duty cycle of the input oscillator waveforms is a 50 percent duty cycle.

6. The circuit as recited in claim 1 wherein the selected ones of the input oscillator waveforms correspond to a 25 percent duty cycle waveform.

7. The circuit as recited in claim 1 wherein the selected ones of the input oscillator waveforms are selected from the group consisting of:
in-phase waveforms;
complementary in-phase waveforms;
quadrature-phase waveforms; and
complementary quadrature-phase waveforms.

8. A method of operating a gated divider circuit, comprising:
providing oscillator waveforms having a fixed duty cycle;
generating windowing waveforms based on the oscillator waveforms; and
selecting ones of the oscillator waveforms as controlled by corresponding ones of the windowing waveforms.

9. The method as recited in claim 8 wherein the corresponding selected ones of the windowing waveforms provide a windowing delay with respect to the selected ones of the input oscillator waveforms.

10. The method as recited in claim 8 wherein the windowing waveforms are 50 percent duty cycle waveforms.

11. The method as recited in claim 8 wherein the fixed duty cycle of the input oscillator waveforms is a 50 percent duty cycle.

12. The method as recited in claim 8 wherein the selected ones of the input oscillator waveforms correspond to a 25 percent duty cycle waveform.

13. The method as recited in claim 8 wherein the selected ones of the input oscillator waveforms are selected from the group consisting of:
in-phase waveforms;
complementary in-phase waveforms;
quadrature-phase waveforms; and
complementary quadrature-phase waveforms.

14. A frequency conversion system, comprising:
a local oscillator divider, including:
a windowing unit that generates windowing waveforms from local oscillator waveforms having a fixed duty cycle, and
a gated output unit that provides selected ones of the local oscillator waveforms as controlled by corresponding selected ones of the windowing waveforms; and
a mixer that provides a converted waveform from the selected ones of the local oscillator waveforms and a reference waveform.

15. The system as recited in claim 14 wherein the corresponding selected ones of the windowing waveforms provide a windowing delay with respect to the selected ones of the input oscillator waveforms.

16. The system as recited in claim 14 wherein the windowing waveforms are 50 percent duty cycle waveforms.

17. The system as recited in claim 14 wherein the fixed duty cycle of the input oscillator waveforms is a 50 percent duty cycle.

18. The system as recited in claim 14 wherein the selected ones of the input oscillator waveforms correspond to a 25 percent duty cycle waveform.

19. The system as recited in claim 14 wherein the selected ones of the input oscillator waveforms are selected from the group consisting of:
in-phase waveforms;
complementary in-phase waveforms;
quadrature-phase waveforms; and
complementary quadrature-phase waveforms.

20. The system as recited in claim 14 wherein the converted waveform is a down-converted waveform or an up-converted waveform.
